(19) United States
(12) Patent Application Publication
(10) Pub. No.: US 2025/0120233 A1
(43) Pub. Date: Apr. 10, 2025

(54) TRANSFER METHOD FOR MICRO FLIP CHIPS

(71) Applicants: XIAMEN UNIVERSITY, Xiamen, Fujian (CN); TAN KAH KEE INNOVATION LABORATORY, Xiamen, Fujian (CN)

(72) Inventors: Xu YANG, Xiamen (CN); Kai HUANG, Xiamen (CN); Jinchai LI, Xiamen (CN); Rong ZHANG, Xiamen (CN)

(73) Assignees: XIAMEN UNIVERSITY, Xiamen, Fujian (CN); TAN KAH KEE INNOVATION LABORATORY, Xiamen, Fujian (CN)

(21) Appl. No.: 18/567,318

(22) PCT Filed: Apr. 14, 2023
(86) PCT No.: PCT/CN2023/088493

§ 371 Date: Dec. 5, 2023

(30) Foreign Application Priority Data
Aug. 2, 2022 (CN) 202210922999.X

(51) Int. Cl. H10H 29/03; H01L 21/66

(52) U.S. Cl. CPC H10H 29/03; H01L 22/12

(57) ABSTRACT

A transfer method for micro flip chips includes forming a first bonding member on a surface of one side of a second electrical connection piece of each of a plurality of micro flip chips facing away from a temporary substrate to which they are adhered. The micro flip chips are transferred onto a drive substrate. The second electrical connection pieces of the micro flip chips are connected to a corresponding one of first electrical connection pieces of the drive substrate via the first bonding members. The micro flip chips are inspected to determine bad point positions of defective chips on the drive substrate. The first bonding member is irradiated at each bad point position by laser and the defective chip is removed. The method ensures stable bonding between the micro flip chips and the drive substrate and prevents the first electrical connection pieces from being damaged by laser irradiation.

### CROSS-REFERENCE TO RELATED APPLICATIONS

The present application claims priority to Chinese patent application No. 202210922999.X, entitled “TRANSFER METHOD FOR MICRO FLIP CHIPS”, filed on Aug. 2, 2022, the content of which is incorporated herein by reference.

### TECHNICAL FIELD

The present application relates to the technical field of chip assembly, in particular to a transfer method for micro flip chips.

### BACKGROUND

A Micro-LED display technology refers to a display technology that uses self-luminescent Micro-LEDs as light-emitting pixel units to assemble them to a drive substrate to form a high-density LED array. Due to the characteristics of small size, high integration and self illumination of a Micro-LED chip, compared with an LCD and an OLED, the Micro-LED chip has greater advantages in brightness, resolution, contrast, energy consumption, service life, response speed, thermal stability and other aspects, and is considered as one of the most promising novel display and light-emitting devices. Currently, the industry generally expects that an important entry point that the Micro-LED display technology can replace an existing OLED and liquid crystal display technology is display products applied in display scenarios with medium and low resolution (PPI), such as small-size wearable devices, TV displays and oversized display walls. For the display products with the medium and low PPI, after manufacturing Micro-LED chip wafers and drive substrates, it is necessary to move millions or even tens of millions of Micro-LED chips to the drive substrates through a massive transfer technology, so that first electrical connection pieces on the drive substrates are electrically connected with second electrical connection pieces on the Micro-LED chips.

A transfer yield is one of the main technical difficulties in a massive transfer process. Even if an overall transfer yield is as high as 99.99%, transferring an 8K television still requires repairing more than a half million of defective chips, and the defective chips are randomly distributed. A selective laser repair technology is the most potential technology that can achieve mass production among various Micro-LED bad point repair technologies. This technology can achieve efficient removal of a large number of random defective chips through high-speed scanning of laser galvanometers and precise control of displacement platforms.

However, laser emitted by the selective laser repair technology is prone to causing irreversible damage to the first electrical connection pieces on the drive substrates, making them unable to be used to connect replacement chips, resulting in the inability to reuse original bonding positions.

### SUMMARY OF THE INVENTION

Therefore, the technical problem to be solved by the present application is to overcome the defect of an existing selective laser repair technology that original bonding positions cannot be reused after defective chips are removed, thereby providing a transfer method for micro flip chips.

The present application provides a transfer method for micro flip chips, including: providing a drive substrate, first electrical connection pieces being formed on a surface of one side of the drive substrate; providing a temporary substrate, a plurality of micro flip chips being adhered to a surface of one side of the temporary substrate, and a second electrical connection piece being formed on a surface of one side of each of the micro flip chips facing away from the temporary substrate; forming a first bonding member on a surface of one side of the second electrical connection piece of each of the micro flip chips facing away from the temporary substrate, the first bonding member being made of material of conductive adhesive; transferring the plurality of micro flip chips onto the drive substrate, and connecting the second electrical connection pieces of the micro flip chips to a corresponding one of the first electrical connection pieces via the first bonding member; inspecting the plurality of micro flip chips to determine any bad point position of defective chip on the drive substrate; and irradiating the first bonding member at each bad point position by laser, and removing the defective chip.

Optionally, the step of forming a first bonding member on a surface of one side of the second electrical connection piece of each of the micro flip chips facing away from the temporary substrate includes: coating the conductive adhesive onto the surface of one side of the second electrical connection piece of each of the micro flip chips facing away from the temporary substrate; or, immersing the surface of one side of the second electrical connection piece of each of the micro flip chips facing away from the temporary substrate into a conductive adhesive solution; and removing the micro flip chips from the conductive adhesive solution, so that the surface of one side of the second electrical connection piece of each of the micro flip chips becomes coated with conductive adhesive.

Optionally, a thickness of the first bonding member is 2 μm to 10 μm.

Optionally, the transfer method for micro flip chips further includes: providing replacement chips, a surface of one side of each of the replacement chips being formed with the second electrical connection piece; forming a second bonding member on a surface of one side of the second electrical connection piece of each of the replacement chips, the second bonding member being made of material of conductive adhesive; and transferring, after removing each of the defective chips, the replacement chips onto each bad point position, and connecting the second electrical connection piece of each of the replacement chips to a corresponding one of the first electrical connection pieces at each bad point position via the second bonding member.

Optionally, the step of forming a second bonding members on a surface of one side of the second electrical connection piece of each of the replacement chips includes: coating the conductive adhesive onto the surface of one side of the second electrical connection piece of each of the replacement chip; or, immersing the surface of one side of the second electrical connection piece of each of the replacement chips into the conductive adhesive solution; and removing the replacement chips from the conductive adhesive solution, so that the surface of one side of the second electrical connection piece of each of the replacement chips becomes coated with conductive adhesive.

Optionally, a process of transferring each of the replacement chips onto each bad point position includes a laser transfer process or an elastic stamp transfer process.

Optionally, a thickness of the second bonding member is 2 μm to 10 μm.

Optionally, the conductive adhesive includes an organic adhesive solution and micro-nano-level conductive particles which are uniformly dispersed in the organic adhesive solution, and a volume percentage of the conductive particles in the conductive adhesive is 10% to 40%.

Optionally, the conductive adhesive includes isotropic conductive adhesive.

Optionally, the conductive particles include metal particles or composite metal particles, and each of the composite metal particles include a particle body and a metal layer wrapping the particle body.

Optionally, the metal particles are made of material of silver, nickel or copper, the metal layer is made of material of silver, and the particle body is made of material of at least one of nickel, copper and carbon nanotubes.

Optionally, the conductive particles have a flake shape, a vertical size of the conductive particles is smaller than a transverse size of the conductive particles, and the transverse size thereof is 1 μm to 20 μm.

Optionally, a material of the organic adhesive solution is a thermosetting material or a thermoplastic material.

Optionally, a material of the organic adhesive solution is a thermosetting material.

Optionally, the thermosetting material includes epoxy resin, cyanate ester resin and polyimide.

Optionally, an energy density of the laser is 100 mJ/cm² to 800 mJ/cm².

Optionally, the laser is ultraviolet laser.

Optionally, a wavelength of the laser is 240 nm to 380 nm.

Optionally, a process of transferring the plurality of micro flip chips onto the drive substrate includes a laser transfer process or an elastic stamp transfer process.

Optionally, the first electrical connection pieces include contact electrodes which are arranged in an array, the contact electrodes being located on the surface of one side of the drive substrate, and first protrusion points each of which is located on a surface of one side of each of the contact electrodes facing away from the drive substrate; the second electrical connection pieces are electrodes of the micro flip chips; or, the second electrical connection pieces include electrodes of the micro flip chips and second protrusion points covering the electrodes.

Optionally, the micro flip chips include Micro-LED chips.

The technical solution of the present application has the following advantages.

1. According to the transfer method for the micro flip chips provided by the present application, the conductive adhesive is adopted as the first bonding members for electrically connecting the micro flip chips with the drive substrate. On the one hand, the conductive adhesive can ensure stable bonding between the micro flip chips and the drive substrate, on the other hand, organic materials in the conductive adhesive at the bad point positions absorb laser energy and undergo gasification in a laser irradiation process, and airflow generated by gasification of the organic materials separates the defective chips from the drive substrate; and the separation of the defective chips and the drive substrate can be achieved immediately when the laser is irradiated to the conductive adhesive, and the energy of the laser is mainly absorbed and released by the organic materials, so that the energy which actually acts on the first electrical connection pieces of the drive substrate is low, the first electrical connection pieces are prevented from being damaged by laser irradiation, so that original bonding welding points can continue to be used, and high efficiency of removing the defective chips is achieved.

2. According to the transfer method for the micro flip chips provided by the present application, the micro flip chips include the Micro-LED chips. In the above transfer method for the micro flip chips, the first electrical connection pieces can be used for being electrically connected with the replacement chips, so that an original bonding position can be used for displaying images, which is conducive to improving a display effect of a Micro-LED display technology.

3. According to the transfer method for the micro flip chips provided by the present application, the thickness of the first bonding members is defined to be 2 μm to 10 μm, the stable bonding between the micro flip chips and the drive substrate is ensured, time for the laser to act on the first bonding members is further shortened, and the efficiency of removing the defective chips is ensured.

4. According to the transfer method for the micro flip chips provided by the present application, the volume percentage of the conductive particles in the conductive adhesive is defined to be 10% to 40%, the stable bonding between the micro flip chips and the drive substrate is ensured, and an electrical connection effect between the micro flip chips and the drive substrate is further facilitated.

5. According to the transfer method for the micro flip chips provided by the present application, the material of the organic adhesive solution is the thermosetting material optionally, that is, the organic materials in the first bonding members and the second bonding members are the thermosetting materials optionally, a stable structure can be obtained after the thermosetting materials are heated and cured for the first time, in a using process, it will not be softened due to too high environmental temperature, and the stable bonding between the micro flip chips and the drive substrate is ensured.

### BRIEF DESCRIPTION OF THE DRAWINGS

In order to explain specific implementations of the present application or technical solutions in the prior art more clearly, accompanying drawings used in description of the specific implementations or the prior art will be briefly introduced below. Obviously, the accompanying drawings in the following description are some implementations of the present application. For those ordinarily skilled in the art, other accompanying drawings may further be obtained according to these accompanying drawings without any creative labor.

FIG. 1 to FIG. 2 are schematic diagrams of a selective laser repair technology.

FIG. 3 is a process flowchart of a transfer method for micro flip chips provided by an embodiment of the present application.

FIG. 4 to FIG. 16 are schematic structural diagrams in a transfer process of micro flip chips of an embodiment of the present application.

### DESCRIPTION OF REFERENCE NUMERALS

1—drive substrate; 11—contact electrode; 12—first initial protrusion point; 13—first protrusion point; 2—temporary substrate; 21—adhesion layer; 3—micro flip chip; 31—second protrusion point; 32—defective chip; 4—first bonding member; 41—conductive adhesive solution; 5—laser; 6—replacement chip; 7—second bonding member; 1′—drive substrate; 11′—contact electrode; 13′—first protrusion point; 3′—micro flip chip; 31′—second protrusion point; 32′—defective chip; and 5′—laser.

### DETAILED DESCRIPTION

As described in the background, the use of an existing selective laser repair technology to remove defective chips results in the inability to reuse an original bonding position.

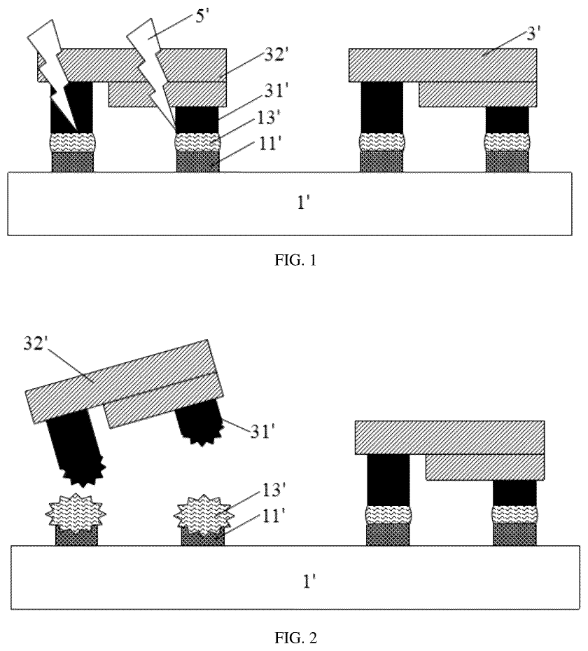

Specifically, bonding between micro flip chips and a drive substrate is usually achieved by alloying first electrical connection pieces of the drive substrate with second electrical connection pieces of the micro flip chips. Exemplarily, as shown in FIG. 1, the first electrical connection pieces include contact electrodes 11′ located on a surface of one side of the drive substrate 1′, and first protrusion points 13′ located on surfaces of one sides of the contact electrodes 11′ facing away from the drive substrate 1′, the first electrical connection pieces include electrodes (not shown in the figure) of the micro flip chips 3′, and second protrusion points 31′ covering the electrodes, alloys are formed at connections between the first protrusion points 13′ and the second protrusion points 31′, and the alloys are irradiated by laser 5′. As shown in FIG. 2, after a certain period of laser irradiation on the alloys, the alloys are melted and damaged, so as to remove defective chips 32′, at this time, the first electrical connection pieces do not have the original morphology, that is, the morphology of the first electrical connection pieces is damaged, the first electrical connection pieces cannot be used to connect replacement chips to meet a requirement of repairing bonding, and the original bonding position cannot be reused. At the same time, due to a high melting point of the alloys, laser irradiation takes a relatively long time to cause fusion welding fracture, and thus the removing efficiency of the defective chips is limited to a certain extent.

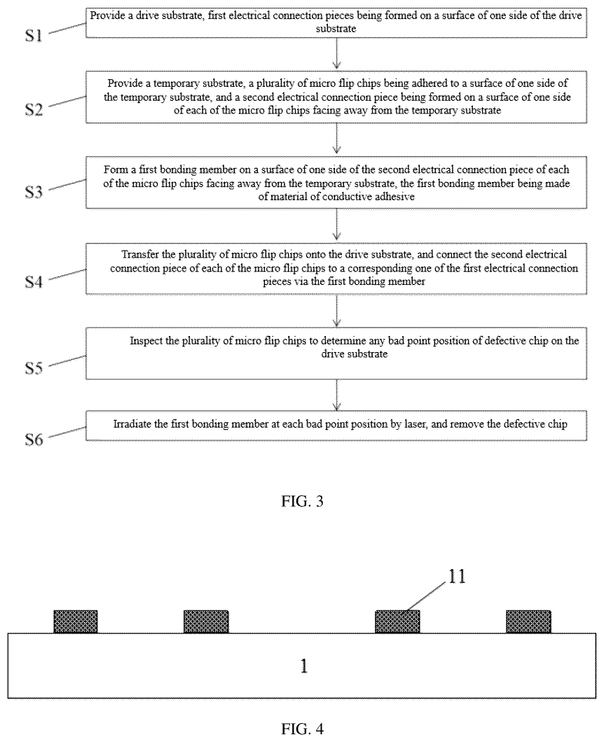

For this purpose, referring to FIG. 3, this embodiment provides a transfer method for micro flip chips, including:
S1, a drive substrate is provided, first electrical connection pieces being formed on a surface of one side of the drive substrate;
S2, a temporary substrate is provided, a plurality of micro flip chips being adhered to a surface of one side of the temporary substrate, and a second electrical connection piece being formed on a surface of one side of each of the micro flip chips facing away from the temporary substrate;
S3, a first bonding member is formed on a surface of one side of the second electrical connection piece of each of the micro flip chips facing away from the temporary substrate, the first bonding member being made of material of conductive adhesive;
S4, the plurality of micro flip chips are transferred onto the drive substrate, and the second electrical connection piece of each of the micro flip chips is connected to a corresponding one of the first electrical connection pieces via the first bonding member;
S5, the plurality of micro flip chips are inspected, and any bad point position of defective chip on the drive substrate is determined; and
S6, the first bonding member at each bad point position is irradiated by laser, and the defective chip is removed.

According to the above transfer method for the micro flip chips, the conductive adhesive is adopted as the first bonding members for electrically connecting the micro flip chips with the drive substrate. On the one hand, the conductive adhesive can ensure stable bonding between the micro flip chips and the drive substrate, on the other hand, organic materials in the conductive adhesive at the bad point positions absorb laser energy and undergo gasification in a laser irradiation process, and airflow generated by gasification of the organic materials separates the defective chips from the drive substrate; and the separation of the defective chips and the drive substrate can be achieved immediately when the laser is irradiated to the conductive adhesive, and the energy of the laser is mainly absorbed and released by the organic materials, so that the energy which actually acts on the first electrical connection pieces of the drive substrate is low, the first electrical connection pieces are prevented from being damaged by laser irradiation, so that original bonding welding points can continue to be used, and high efficiency of removing the defective chips is achieved.

A specific principle of separating the defective chips by laser irradiation is as follows: after the first bonding members are subjected to laser irradiation, organic materials in the first bonding members absorb photons, which promote the chemical bond fracture of organic macromolecules and form organic small molecules. Due to high photon density in the laser, the rate of chemical bond fracture in the first bonding members exceeds the rate of chemical bond recombination, resulting in rapid decomposition of the organic macromolecules into organic small molecules in the first bonding members. The presence of these organic small molecules leads to a sudden increase in specific volume, a sharp increase in pressure and a rapid expansion in volume of the first bonding members, and ultimately a volume explosion, causing the defective chips to be removed and carry excess heat.

Further, the micro flip chips include Micro-LED chips. In the above transfer method for the micro flip chips, the first electrical connection pieces can be used for being electrically connected with the replacement chips, so that an original bonding position can be used for displaying images, which is conducive to improving a display effect of a Micro-LED display technology.

Specifically, the first electrical connection pieces include contact electrodes which are arranged in an array, the contact electrodes being located on the surface of one side of the drive substrate, and first protrusion points each of which is located on a surface of one side of each of the contact electrodes facing away from the drive substrate. The second electrical connection pieces are electrodes of the micro flip chips; or, the second electrical connection pieces include the electrodes of the micro flip chips and second protrusion points covering the electrodes.

Taking the second electrical connection pieces including the electrodes of the micro flip chips and the second protrusion points covering the electrodes as an example below, the technical solutions of the present application are clearly and completely described in conjunction with FIG. 4 to FIG. 16.

Referring to FIG. 4, a drive substrate 1 is provided, and contact electrodes 11 which are arranged in an array are formed on a surface of one side of the drive substrate 1.

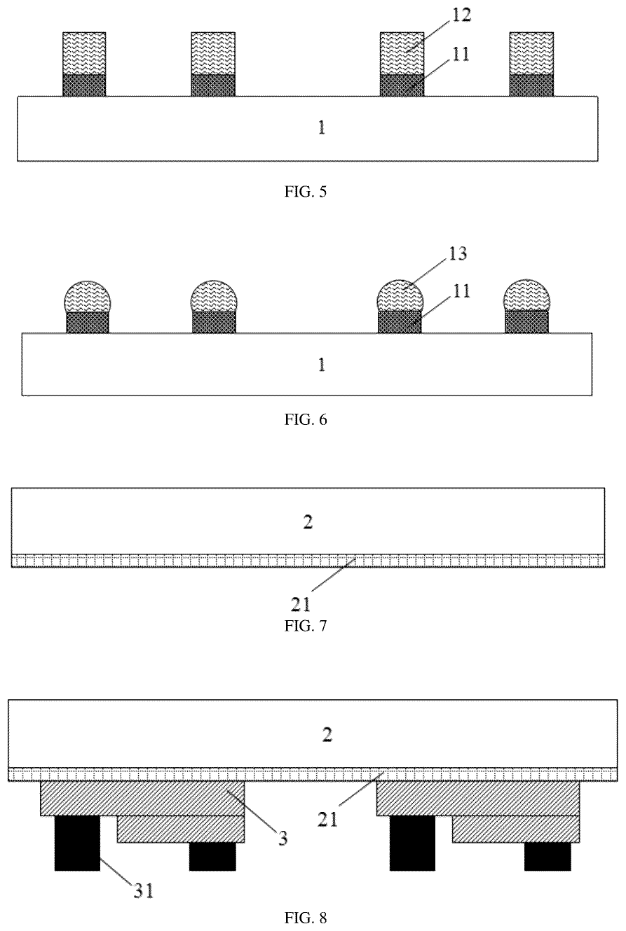

Referring to FIG. 5, first initial protrusion points 12 are formed on surfaces of one sides of the contact electrodes 11 facing away from the drive substrate 1.

Specifically, the first initial protrusion points 12 are made of material of, not limited to, at least one of In, Sn, Ag, Au and Cu.

Referring to FIG. 6, reflux soldering is performed on the first initial protrusion points 12, so that the first initial protrusion points 12 form first protrusion points 13.

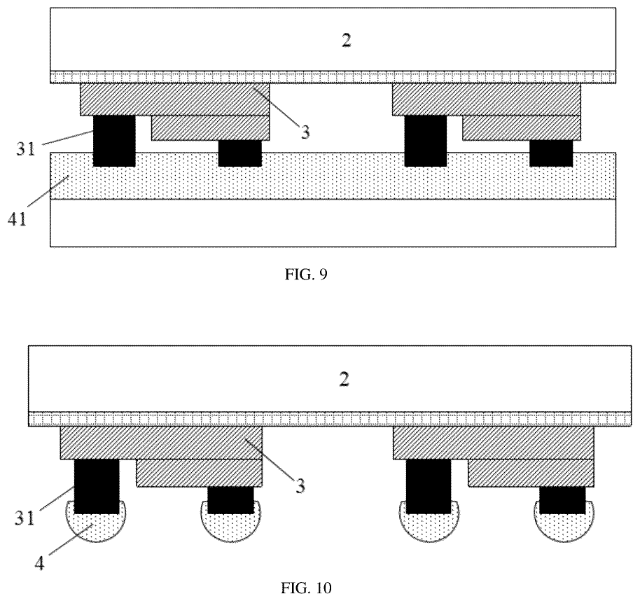

Referring to FIG. 7, a temporary substrate 2 is provided, and an adhesion layer 21 is formed on a surface of one side of the temporary substrate 2.

Referring to FIG. 8, micro flip chips 3 are classified in arrays and transferred to the temporary substrate 2, the micro flip chips 3 are adhered to the adhesion layer 21, electrodes of the micro flip chips 3 and second protrusion points 31 covering the electrodes all face away from the temporary substrate 2, and the electrodes and the second protrusion points 31 constitute second electrical connection pieces.

Referring to FIG. 9 to FIG. 10, a first bonding member 4 is formed on a surface of one side of the second electrical connection piece of each of the micro flip chips 3 facing away from the temporary substrate 2, and the first bonding member 4 is made of material of conductive adhesive.

Specifically, the step of forming the first bonding member 4 on a surface of one side of the second electrical connection piece of each of the micro flip chips 3 facing away from the temporary substrate 2 includes: referring to FIG. 9, a surface of one side of the second protrusion point 31 of each of the micro flip chips 3 facing away from the temporary substrate is immersed into a conductive adhesive solution 41; and referring to FIG. 10, the micro flip chips 3 are removed from the conductive adhesive solution 41, and the surface of one side of the second protrusion point 31 of each of the micro flip chips 3 is coated with the conductive adhesive.

Further, the conductive adhesive includes an organic adhesive solution and micro-nano-level conductive particles which are uniformly dispersed in the organic adhesive solution. A material of the organic adhesive solution may be a thermosetting material or a thermoplastic material, such as epoxy resin, cyanate resin, polyimide, cyanoacrylate and silicone; and the conductive particles include metal particles or composite metal particles, each of the composite metal particles includes a particle body and a metal layer wrapping the particle body, the metal particles are made of material of, not limited to, silver, nickel or copper, the metal layer is made of material of silver, and the particle body is made of material of, not limited to, at least one of nickel, copper and carbon nanotubes.

As an optional implementation, a material of the organic adhesive solution is a thermosetting material, that is, the organic materials in the first bonding members 4 are the thermosetting materials optionally. A stable structure can be obtained after the thermosetting materials are heated and cured for the first time, in a using process, it will not be softened due to too high environmental temperature, and the stable bonding between the micro flip chips 3 and the drive substrate 1 is ensured.

Further, a volume percentage of the conductive particles in the conductive adhesive is 10% to 40%. Exemplarily, the volume percentage of the conductive particles may be 10%, 15%, 20%, 25%, 30%, 35% or 40%. If the volume percentage of the conductive particles is too small, the volume percentage of the organic adhesive solution is too large, which is beneficial for the stable bonding between the micro flip chips 3 and the drive substrate 1, but leads to poor conductivity of the bonding members, thereby limiting the electrical connection effect between the micro flip chips 3 and the drive substrate 1. If the volume percentage of the conductive particles is too large, the volume percentage of the organic adhesive solution is too small, which is beneficial for the electrical connection effect between the micro flip chips 3 and the drive substrate 1, but not beneficial for the stability of connection between the micro flip chips 3 and the drive substrate 1. The volume percentage of the conductive particles in the conductive adhesive is defined to be 10% to 40%, the stable bonding between the micro flip chips 3 and the drive substrate 1 is ensured, and the electrical connection effect between the micro flip chips 3 and the drive substrate 1 is further facilitated.

Optionally, the conductive particles have a flake shape, a vertical size of the conductive particles is smaller than a transverse size of the conductive particles, and the transverse size thereof is 1 μm to 20 μm. Exemplarily, the transverse size of the conductive particles is 1 μm, 2.5 μm, 5 μm, 7.5 μm, 10 μm, 12.5 μm, 15 μm, 17.5 μm or 20 μm.

Further, the conductive adhesive may be isotropic conductive adhesive optionally, and may also be anisotropic conductive adhesive optionally. Optionally, the conductive adhesive is the isotropic conductive adhesive, and the isotropic conductive adhesive can ensure the electrical connection ability of the first bonding members 4.

It needs to be understood that the first bonding members 4 may also be formed by coating the conductive adhesive onto the surfaces of the second protrusion points 31, or the first bonding members 4 are formed by other micro-nano processing modes.

Further, a thickness of the first bonding members 4 is 2 μm to 10 μm. Exemplarily, the thickness of the first bonding members 4 may be 2 μm, 3 μm, 4 μm, 5 μm, 6 μm, 7 μm, 8 μm, 9 μm or 10 μm. When the first bonding members 4 are too thin, the adhering stability between the micro flip chips 3 and the drive substrate 1 cannot be ensured; and when the first bonding members 4 are too thick, it requires the laser 5 to irradiate the first bonding members 4 for a long time to achieve the separation of the defective chips, reducing the efficiency of removing the defective chips. The thickness of the first bonding member 4 is defined to be 2 μm to 10 μm, the stable bonding between the micro flip chips 3 and the drive substrate 1 is ensured, time for the laser 5 to act on the first bonding members 4 is further shortened, and the efficiency of removing the defective chips is ensured.

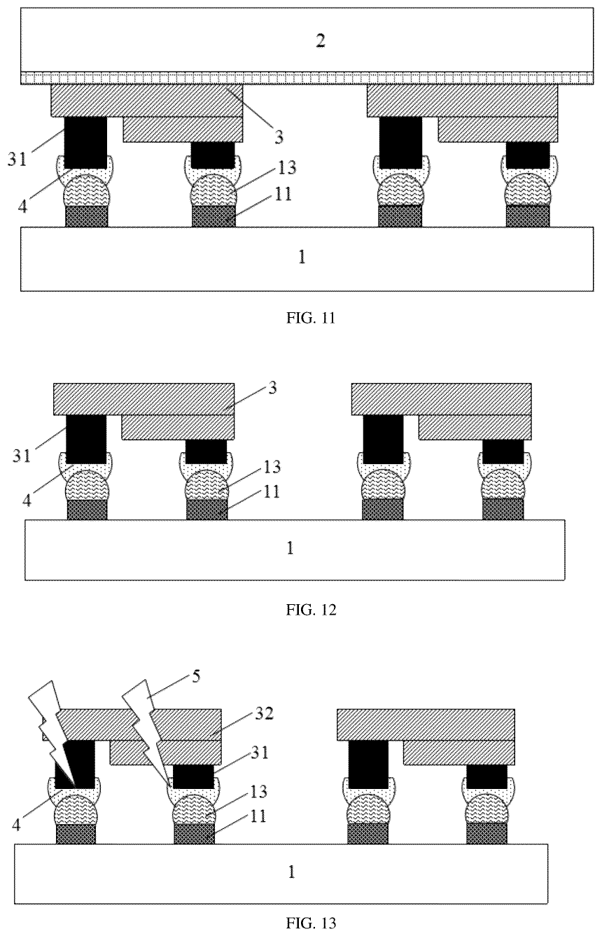

Referring to FIG. 11 and FIG. 12, the plurality of micro flip chips 3 are transferred onto the drive substrate 1, and the second electrical connection piece of each of the micro flip chips 3 is connected to a corresponding one of the first electrical connection pieces via the first bonding member 4, so that the micro flip chips 3 are bonded with the drive substrate 1.

Specifically, referring to FIG. 11, the temporary substrate 2 and the drive substrate 1 are arranged oppositely, so that the first bonding members 4 on one sides of the micro flip chips 3 are bonded with the first protrusion points 13 on the surface of the drive substrate 1; and referring to FIG. 12, the temporary substrate 2 is removed, and the adhesion layer 21 on the surface of one side of the temporary substrate 2 is also removed together. The process of transferring the plurality of micro flip chips 3 onto the drive substrate 1 includes, but is not limited to a laser transfer process or an elastic stamp transfer process.

After the micro flip chips 3 are bonded with the drive substrate 1, the plurality of micro flip chips 3 on the drive substrate 1 are inspected, and any bad point position of the defective chip on the drive substrate 1 is determined. Specifically, the inspection includes optical inspection and electrical inspection; and after any bad point position of the defective chip on the drive substrate 1 is determined, coordinate values of the bad point positions on the drive substrate 1 are obtained, and a coordinate system takes an edge of the drive substrate 1 as a coordinate axis.

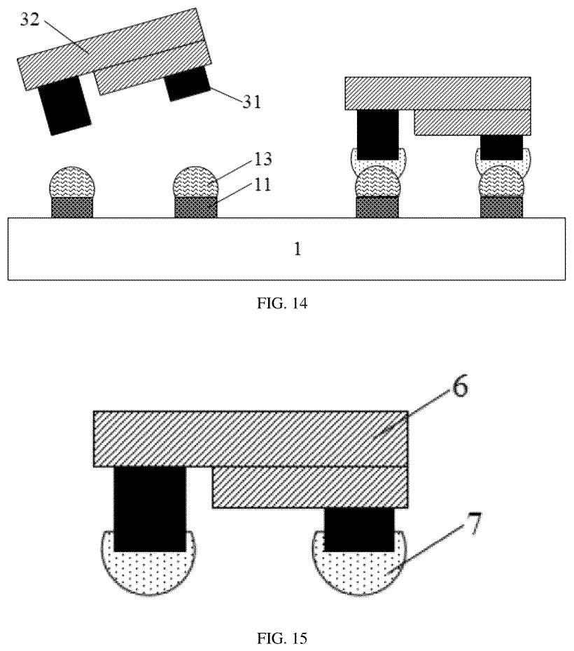

Referring to FIG. 13 and FIG. 14, the first bonding members 4 at the bad point positions are irradiated by the laser 5, and the defective chips 32 are removed.

Specifically, referring to FIG. 13, the laser 5 is irradiated to the first bonding members 4 through the defective chips 32, a size of laser spots is matched with a size of the micro flip chips 3, that is, the size of the laser spots is greater than or equal to the size of the micro flip chips, and only one micro flip chip is covered. Exemplarily, the plurality of micro flip chips are arranged in an array, a pitch between central axes of the adjacent micro flip chips is the same, a projection on an array substrate of the micro flip chips is a rectangle (a×b), and then the size of the laser spots is greater than or equal to a×b and smaller than or equal to (Pitch×2−a)×(Pitch×2−b); when a=15 μm, b=25 μm, and Pitch=35 μm, the size of the laser spots is greater than or equal to 15 μm×25 μm and smaller than or equal to 55 μm×45 μm.

Further, an energy density of the laser 5 is 100 mJ/cm² to 800 mJ/cm². Exemplarily, the energy density of the laser 5 may be 100 mJ/cm², 200 mJ/cm², 300 mJ/cm², 400 mJ/cm², 500 mJ/cm², 600 mJ/cm², 700 mJ/cm² or 800 mJ/cm².

Further, the laser 5 may be ultraviolet laser. The organic materials in the first bonding members 4 have a strong absorption effect on ultraviolet light, so that the defective chips 32 have high separation efficiency. Optionally, a wavelength of the laser 5 is 240 nm to 380 nm; and exemplarily, the wavelength of the laser 5 may be 248 nm, 266 nm, 280 nm, 355 nm, 365 nm or 375 nm.

Further, the laser 5 is single pulse laser with a pulse width of nanoseconds or picoseconds.

Referring to FIG. 15, replacement chips 6 are provided, and a second electrical connection piece is formed on a surface of one side of each of the replacement chips; and a second bonding member 7 is formed on a surface of one side of the second electrical connection piece of each of the replacement chips 6, and the second bonding member 7 is made of material of conductive adhesive. Structures of the replacement chips 6 are the same as those of the original micro flip chips at the bad point positions.

Specifically, the step of forming a second bonding member 7 on a surfaces of one side of the second electrical connection piece of each of the replacement chips 6 includes: a surface of one side of a second protrusion point of each of the replacement chips 6 is immersed into a conductive adhesive solution 41; and the replacement chips 6 are removed from the conductive adhesive solution 41, and the surface of one side of the second protrusion point of each of the replacement chips 6 is coated with the conductive adhesive. The second bonding member 7 may also be formed by coating the conductive adhesive onto the surface of one side of the second protrusion point of each of the replacement chips 6. The method for forming the second bonding member 7 includes, but is not limited to the above mode.

Further, materials of the second bonding members 7 may be the same as the materials of the first bonding members 4, which will not be repeated here.

Further, a thickness of the second bonding members 7 is 2 μm to 10 μm. Exemplarily, the thickness of the second bonding members 7 may be 2 μm, 3 μm, 4 μm, 5 μm, 6 μm, 7 μm, 8 μm, 9 μm or 10 μm. The thickness of the second bonding members 7 is defined to be 2 μm to 10 μm, the stable bonding between the micro flip chips 3 and the drive substrate 1 is ensured, sufficient airflow is further generated after the laser acts on the second bonding members 7, and the efficiency of removing the defective chips 32 is ensured.

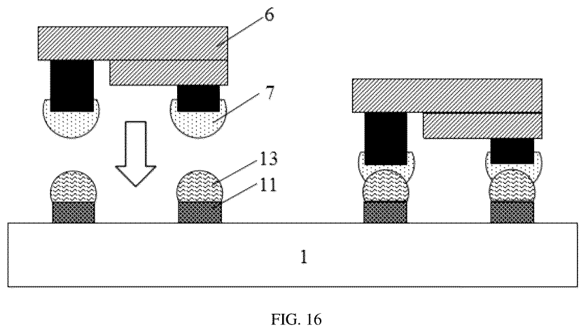

Referring to FIG. 16, after removing the defective chips 32, the replacement chips 6 are transferred to the bad point positions, and the second electrical connection pieces of the replacement chips 6 are connected with the first electrical connection pieces at the bad point positions by the second bonding members 7.

Specifically, the process of transferring the replacement chips 6 to the bad point positions includes, but is not limited to a laser transfer process or an elastic stamp transfer process.

It needs to be understood that before removing the defective chips 32, the second bonding members 7 may be formed on the surfaces of the second protrusion points of the replacement chips 6; and after removing the defective chips 32, the replacement chips 6 are directly transferred to the bad point positions, which is conducive to shortening time.

It needs to be understood that inspecting the micro flip chips on the drive substrate, removing the defective chips and transferring the replacement chips constitute an in-situ repair step, and after transferring the replacement chips to the bad point positions, the in-situ repair step may be repeated until there is no bad point on the surface of the drive substrate.

Obviously, the above embodiments are only for the purpose of clearly explaining the examples, not limiting the implementations. For those ordinarily skilled in the art, other changes or variations in different forms may further be made on the basis of the above description. It is unnecessary and impossible to enumerate all the implementations here. However, the obvious changes or variations arising therefrom are still within the scope of protection of the present disclosure. In the description of the present application, the terms “first”, and “second” are only used to describe the purposes, and cannot be understood as indicating or implying relative importance.

1. A transfer method for micro flip chips, comprising:
providing a drive substrate, wherein first electrical connection pieces are formed on a surface of one side of the drive substrate;
providing a temporary substrate, wherein a plurality of micro flip chips are adhered to a surface of one side of the temporary substrate, and a second electrical connection piece is formed on a surface of one side of each of the micro flip chips facing away from the temporary substrate;
forming a first bonding member on a surface of one side of the second electrical connection piece of each of the micro flip chips facing away from the temporary substrate, wherein the first bonding member is made of material of conductive adhesive;
transferring the plurality of micro flip chips onto the drive substrate, and connecting the second electrical connection pieces of the micro flip chips to a corresponding one of the first electrical connection pieces via the first bonding member;
inspecting the plurality of micro flip chips, and determining any bad point position of defective chip on the drive substrate; and
irradiating the first bonding member at the bad point position by laser, and removing the defective chip.

2. The transfer method for the micro flip chips according to claim 1, wherein the step of forming a first bonding member on a surface of one side of the second electrical connection piece of each of the micro flip chips facing away from the temporary substrate comprises:
coating the conductive adhesive onto the surface of one side of the second electrical connection piece of each of the micro flip chips facing away from the temporary substrate; or,
immersing the surface of one side of the second electrical connection piece of each of the micro flip chips facing away from the temporary substrate into a conductive adhesive solution, and removing the micro flip chips from the conductive adhesive solution, so that the surface of one side of the second electrical connection piece of each of the micro flip chips becomes coated with conductive adhesive.

3. The transfer method for micro flip chips according to claim 1, wherein a thickness of the first bonding member is 2 μm to 10 μm.

4. The transfer method for micro flip chips according to claim 1, further comprising:
providing replacement chips, wherein a surface of one side of each of the replacement chips is formed with the second electrical connection piece;
forming a second bonding member on a surface of one side of the second electrical connection piece of each of the replacement chips, wherein the second bonding member is made of material of conductive adhesive; and
transferring, after removing each defective chip, each of the replacement chips onto each bad point position, and connecting the second electrical connection piece of each of the replacement chips to a corresponding one of the first electrical connection piece at each bad point position via the second bonding member.

5. The transfer method for micro flip chips according to claim 4, wherein the step of forming a second bonding member on a surface of one side of the second electrical connection piece of each of the replacement chips comprises:
coating conductive adhesive onto the surface of one side of the second electrical connection piece of each of the replacement chips; or,
immersing the surface of one side of the second electrical connection piece of each of the replacement chips into a conductive adhesive solution; and removing the replacement chips from the conductive adhesive solution, so that the surface of one side of the second electrical connection piece of each of the replacement chips becomes coated with conductive adhesive.

6. The transfer method for micro flip chips according to claim 4, wherein a process of transferring each of the replacement chips onto each bad point position comprises a laser transfer process or an elastic stamp transfer process.

7. The transfer method for micro flip chips according to claim 4, wherein a thickness of the second bonding member is 2 μm to 10 μm.

8. The transfer method for micro flip chips according to claim 2, wherein the conductive adhesive comprises an organic adhesive solution and micro-nano-level conductive particles which are uniformly dispersed in the organic adhesive solution, and a volume percentage of the conductive particles in the conductive adhesive is 10% to 40%.

9. The transfer method for micro flip chips according to claim 8, wherein the conductive adhesives comprise isotropic conductive adhesives.

10. The transfer method for micro flip chips according to claim 8, wherein the conductive particles comprise metal particles or composite metal particles, and each of the composite metal particles comprises a particle body and a metal layer wrapping the particle body.

11. The transfer method for micro flip chips according to claim 10, wherein the metal particles are made of material of silver, nickel or copper, the metal layer is made of material of silver, and the particle body is made of material of at least one of nickel, copper and carbon nanotubes.

12. The transfer method for micro flip chips according to claim 10, wherein the conductive particles have a flake shape, a vertical size of the conductive particles is smaller than a transverse size of the conductive particles, and the transverse size thereof is 1 μm to 20 μm.

13. The transfer method for micro flip chips according to claim 8, wherein a material of the organic adhesive solution is a thermosetting material or a thermoplastic material.

14. The transfer method for micro flip chips according to claim 13, wherein a material of the organic adhesive solution is a thermosetting material that comprises at least one of epoxy resin, cyanate ester resin and polyimide.

15. (canceled)

16. The transfer method for micro flip chips according to claim 1, wherein an energy density of the laser is 100 mJ/cm² to 800 mJ/cm².

17. The transfer method for micro flip chips according to claim 16, wherein the laser is ultraviolet laser.

18. The transfer method for micro flip chips according to claim 16, wherein a wavelength of the laser is 240 nm to 380 nm.

19. The transfer method for micro flip chips according to claim 1, wherein a process of transferring the plurality of micro flip chips onto the drive substrate comprises a laser transfer process or an elastic stamp transfer process.

20. The transfer method for micro flip chips according to claim 1, wherein:
the first electrical connection pieces comprise contact electrodes which are arranged in an array, the contact electrodes being located on the surface of one side of the drive substrate, and first protrusion points each of which is located on a surface of one side of each of the contact electrodes facing away from the drive substrate; and
the second electrical connection pieces are electrodes of the micro flip or the second electrical connection pieces comprise electrodes of the micro flip chips and second protrusion points covering the electrodes.

21. The transfer method for micro flip chips according to claim 1, wherein the micro flip chips comprise Micro-LED chips.
